(19) United States
(12) Patent Application Publication
(10) Pub. No.: US 2011/0018853 A1
(43) Pub. Date: Jan. 27, 2011

(54) SIGNAL LINE DRIVING CIRCUIT AND LIQUID CRYSTAL DISPLAY DEVICE

(75) Inventor: Hirokazu KAWAGOSHI, Kawasaki (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kawasaki (JP)

(21) Appl. No.: 12/796,314

(22) Filed: Jun. 8, 2010

(30) Foreign Application Priority Data
Jul. 23, 2009 (JP) 2009-171825

(51) Int. Cl. G06F 3/038; H03K 3/00

(52) U.S. Cl. 345/211; 327/108

(57) ABSTRACT

A signal line driving circuit according to an exemplary aspect of the present invention includes: a first amplifier; a second amplifier; a first charge share switch connected between an output terminal of the first amplifier and an output terminal of the second amplifier; a first output switch connected between an output node of the first amplifier and the output terminal of the first amplifier; a second charge share switch connected between a node between the first output switch and the output terminal of the first amplifier and an input terminal of the first amplifier; and a first input switch connected to the input terminal of the first amplifier.

### INCORPORATION BY REFERENCE

This application is based upon and claims the benefit of priority from Japanese patent application No. 2009-171825, filed on Jul. 23, 2009, the disclosure of which is incorporated herein in its entirety by reference.

### BACKGROUND

1. Field of the Invention

The present invention relates to a signal line driving circuit and a liquid crystal display device, and more particularly, to a signal line driving circuit that performs a charge sharing operation, and a liquid crystal display device using the same.

2. Description of Related Art

Along with the recent increase in display screen size and resolution of liquid crystal display devices used as displays for televisions and personal computers, an increasing number of differential amplifier circuits and the like have been mounted therein. Accordingly, each signal line driving circuit is required to have a driving performance for driving a larger load at higher speed while suppressing power consumption.

Further, in order to prevent an increase in chip size, the signal line driving circuit is required to be designed to have as small a circuit area as possible. Furthermore, it is necessary to take countermeasures against power supply noise and reduce EMI (Electro Magnetic Interference) by suppressing a peak power supply current during the load driving.

Japanese Unexamined Patent Application Publication No. 11-095729 (Taguma et al.) discloses a signal line driving circuit for liquid crystal display. Referring to FIG. 7 of Taguma et al., the signal line driving circuit disclosed by Taguma et al. will be described. FIG. 7 of Taguma et al. illustrates an exemplary circuit configuration of the main part of the signal line driving circuit.

In the signal line driving circuit, drive units for each channel are independent from each other in parallel. An output amplifier 22 of each channel operates alternately in a positive voltage range and a negative voltage range. In the exemplary configuration shown in FIG. 7 of Taguma et al., an open/close switch 30 is connected between a pair of adjacent channels.

FIG. 5 illustrates a configuration in the vicinity of the output amplifier shown in FIG. 7 of Taguma et al. to explain the technique disclosed by Taguma et al. FIG. 6 illustrates waveforms corresponding to waveforms of adjacent signal lines Xj and Xj+1 disclosed by Taguma et al.

Referring to FIG. 5, an output node SK41 of an odd-numbered amplifier AMP41 is connected to an odd-numbered output terminal SKOUT41 through an output switch SW44 so as to drive a display panel load F41. An output node SG41 of an even-numbered amplifier AMP42 is connected to an even-numbered output terminal SGOUT41 through an output switch SW45 so as to drive a display panel load F42.

A charge share switch SW41 is connected between both the amplifier output terminals (SKOUT41, SGOUT41). A description is given of an operation for dot-inversion driving of the liquid crystal panel using the signal line driving circuit. During a charge sharing operation after completion of one horizontal period, the charge share switch SW41 is turned on and the output switches SW44 and SW45 are turned off. At the same time, the input of each of the odd-numbered amplifier AMP41 and the even-numbered amplifier AMP42 is switched to a set voltage for the subsequent horizontal period.

During the charge sharing operation, the output of each of the odd-numbered amplifier AMP41 and the even-numbered amplifier AMP42 shifts toward the set potential. After completion of the charge sharing operation for the loads, when the charge share switch SW41 is turned off and the output switches SW44 and SW45 are turned on, the output voltages of the odd-numbered amplifier AMP41 and the even-numbered amplifier AMP42 temporarily become unequal to a load voltage.

Referring to FIG. 6, a difference between the output voltage and the load voltage appears as a difference between the final voltage at the output node SK41 and the final voltage at the output terminal SKOUT41, or as a difference between the final voltage at the output node SG41 and the final voltage at the output terminal SGOUT41 in a charge sharing operation period. Particularly, along with the recent increase in the slew rate of source output amplifiers, the difference between the final voltages in the charge sharing operation period becomes more pronounced.

The amplifier output is affected by the load voltage and decreases or increases for a moment. Then, the amplifier output is to be returned to the set voltage for each amplifier, with the result that a large circuit current (GND current) flows. Referring to FIG. 6, the large circuit current appears as a variation in the terminal waveform of the output nodes SK41 and SG41 and as a variation in the waveform of the amplifier GND current.

### SUMMARY

The present inventor has found a problem that after completion of a charge sharing operation, each amplifier output fluctuates and a large circuit current flows through the signal line driving circuit disclosed by Taguma et al.

A first exemplary aspect of the present invention is a signal line driving circuit including: a first amplifier; a second amplifier; a first charge share switch connected between an output terminal of the first amplifier and an output terminal of the second amplifier; a first output switch connected between an output node of the first amplifier and the output terminal of the first amplifier; a second charge share switch connected between a node between the first output switch and the output terminal of the first amplifier and an input terminal of the first amplifier; and a first input switch connected to the input terminal of the first amplifier.

During the charge sharing operation, the first charge share switch and the second charge share switch are turned on, and at the same time, the first output switch and the first input switch are turned off. This allows an output voltage of the first amplifier to be equal to a load voltage after completion of the charge sharing operation. Consequently, the fluctuation in the output of the amplifiers after completion of the charge sharing operation can be suppressed, and the peak circuit current flowing immediately after the charge sharing operation can be reduced.

According to an exemplary aspect of the present invention, it is possible to provide a signal line driving circuit capable of suppressing the fluctuation in the output of each amplifier after completion of the charge sharing operation, and a liquid crystal display device using the same.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a diagram showing a configuration of a liquid crystal display device using a signal line driving circuit according to a first exemplary embodiment of the present invention;

FIG. 2 is a diagram showing operation waveforms of the signal line driving circuit shown in FIG. 1;

FIG. 3 is a diagram showing a configuration of a liquid crystal display device using a signal line driving circuit according to a second exemplary embodiment of the present invention;

FIG. 4 is a diagram showing a configuration of a liquid crystal display device using a signal line driving circuit according to a third exemplary embodiment of the present invention;

FIG. 5 is a diagram illustrating a signal line driving circuit disclosed by Taguma et al.; and

FIG. 6 is a diagram illustrating operation waveforms of the signal line driving circuit disclosed by Taguma et al.

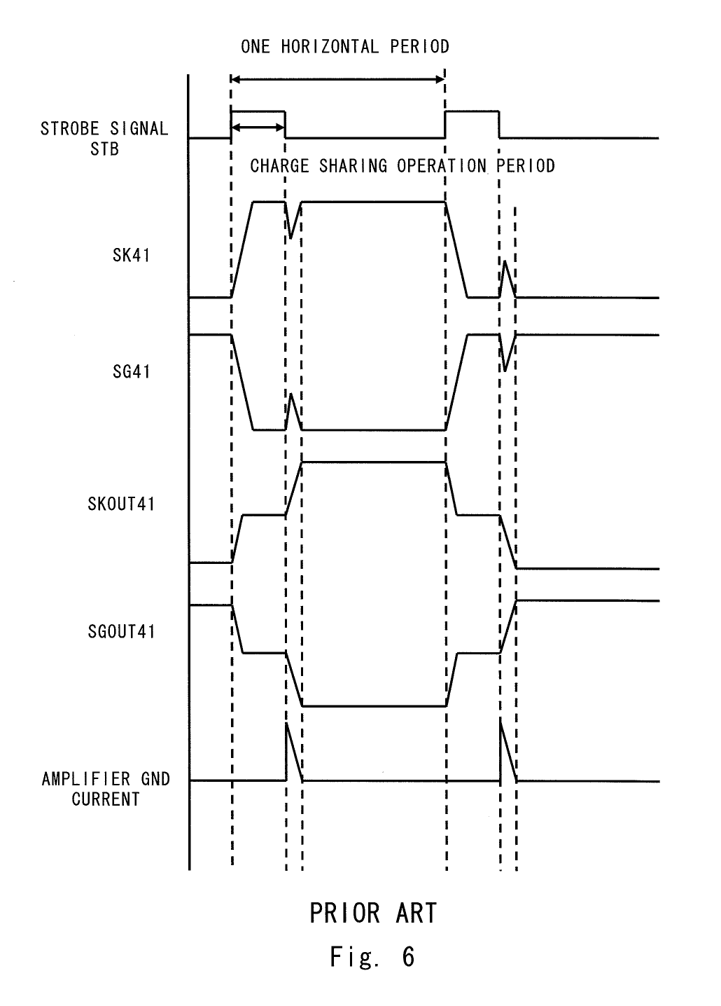

### DETAILED DESCRIPTION OF THE EXEMPLARY EMBODIMENTS

### First Exemplary Embodiment

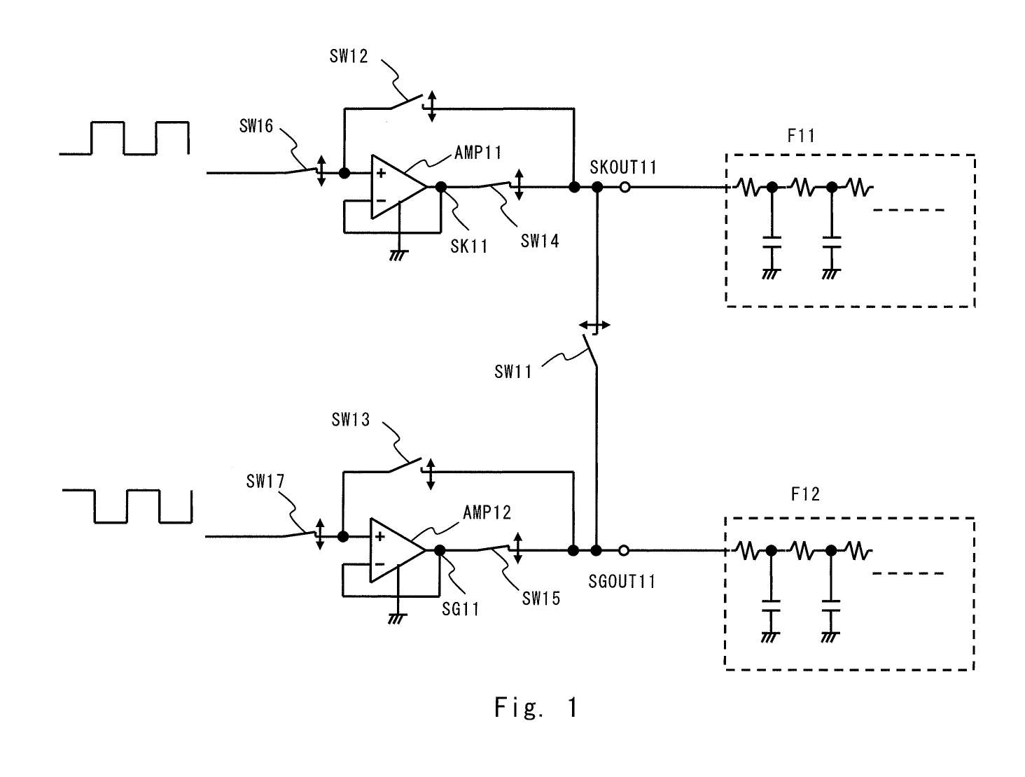

A liquid crystal display device using a signal line driving circuit according to a first exemplary embodiment of the present invention will be described with reference to FIG. 1. FIG. 1 is a diagram showing the configuration of the liquid crystal display device using the signal line driving circuit according to the first exemplary embodiment.

As shown in FIG. 1, the signal line driving circuit according to the first exemplary embodiment includes an odd-numbered amplifier AMP11, an even-numbered amplifier AMP12, charge share switches SW11, SW12, and SW13, output switches SW14 and SW15, and input switches SW16 and SW17.

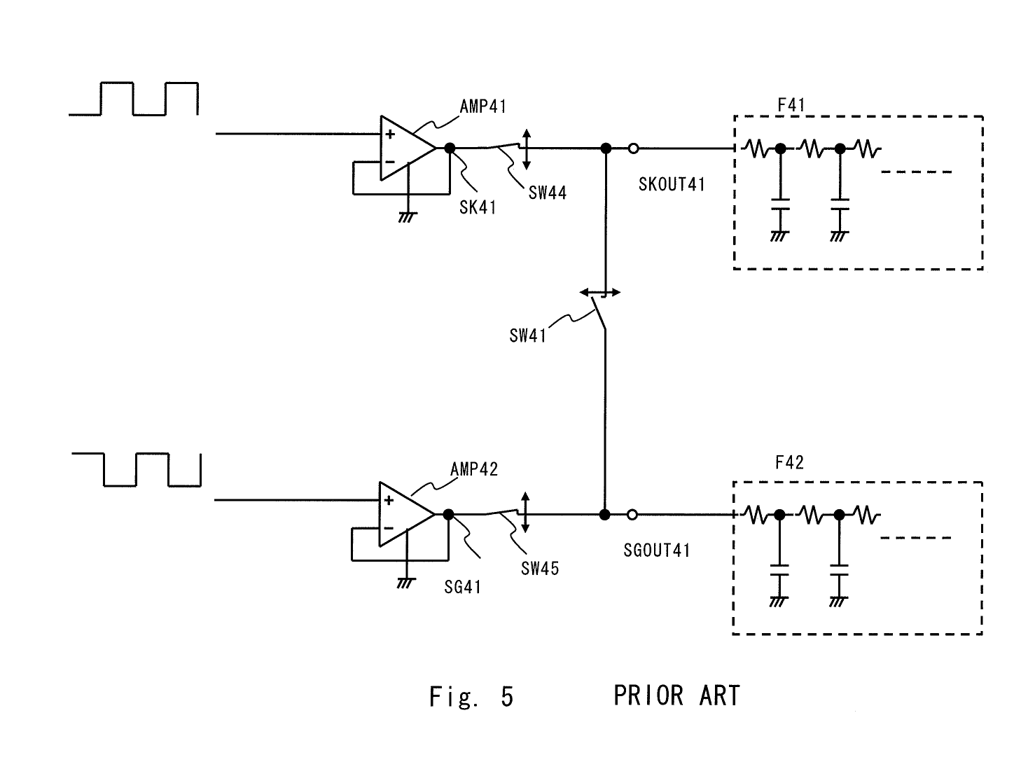

Unlike the configuration shown in FIG. 5, the configuration of the first exemplary embodiment includes the charge share switches SW12 and SW13 and the input switches SW16 and SW17. Note that a common line for charge sharing, which is normally provided, is omitted from the circuit diagram shown in FIG. 1.

A non-inverting input terminal of the odd-numbered amplifier AMP11 is connected to the input switch SW16. An output node SK11 of the odd-numbered amplifier AMP11 is connected to an odd-numbered output terminal SKOUT11 through the output switch SW14. The odd-numbered output terminal SKOUT11 is connected to a load F11 serving as a capacitive load of a liquid crystal panel.

A non-inverting input terminal of the even-numbered amplifier AMP12 is connected to the input switch SW17. An output node SG11 of the even-numbered amplifier AMP12 is connected to an even-numbered output terminal SGOUT11 through the output switch SW15. The even-numbered output terminal SGOUT11 is connected to a load F12 serving as a capacitive load of the liquid crystal panel.

The charge share switch SW11 is connected between the amplifier output terminals (SKOUT11, SGOUT11). Upon turning on of the charge share switch SW11, the potentials of the loads F11 and F12 are equalized. The equalization of the potentials of the loads F11 and F12 is called charge sharing.

The term “charge sharing” refers to an operation in which a precharge operation for applying a voltage to a signal line in advance is performed prior to setting of the potential of the signal line to the set potential for the subsequent horizontal period, by using electric charge accumulated in the signal line of the liquid crystal panel, to which loads of the liquid crystal panel are connected, in a certain horizontal period. The charge sharing operation allows the potential of the signal line to reach a desired set potential earlier, and allows for power saving.

The charge share switch SW12 is connected between the non-inverting input terminal of the odd-numbered amplifier AMP11 and the odd-numbered output terminal SKOUT11. The charge share switch SW12 is connected between a node between the output switch SW14 and the odd-numbered output terminal SKOUT11 and a node between the input switch SW16 and the non-inverting input terminal of the odd-numbered amplifier AMP11.

The charge share switch SW13 is connected between the non-inverting input terminal of the even-numbered amplifier AMP12 and the even-numbered output terminal SGOUT11. The charge share switch SW13 is connected between a node between the output switch SW15 and the even-numbered output terminal SGOUT11 and a node between the input switch SW17 and the non-inverting input terminal of the even-numbered amplifier AMP12.

The charge share switches SW12 and SW13 allow charge share voltages at the loads F11 and F12, which are being subjected to charge sharing, to be transmitted (fed back) to the non-inverting input terminals of the odd-numbered amplifier AMP11 and the even-numbered amplifier AMP12, respectively.

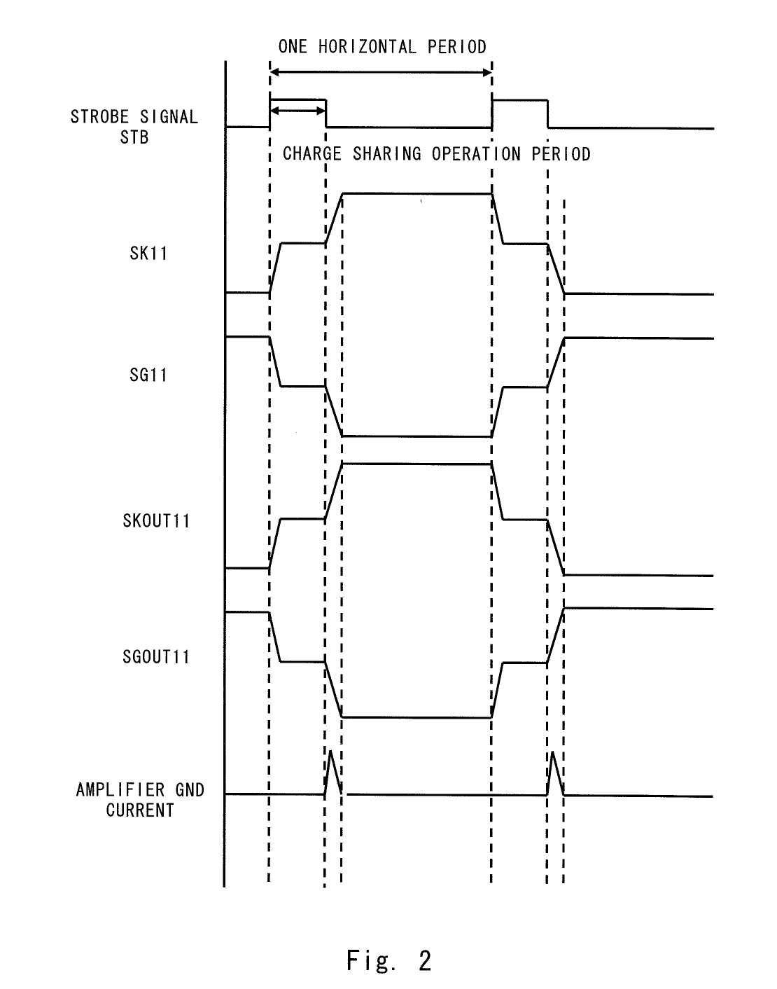

Referring now to FIG. 2, a description is given of an operation for dot-inversion driving of the liquid crystal panel using the signal line driving circuit using the signal line driving circuit. FIG. 2 is a diagram showing operation waveforms of the signal line driving circuit shown in FIG. 1. Referring to FIG. 2, SK11 represents a terminal waveform at the output node SK11, and SG11 represents a terminal waveform at the output node SG11. Further, SKOUT11 represents a terminal waveform at the odd-numbered output terminal SKOUT11, and SGOUT11 represents a terminal waveform at the even-numbered output terminal SGOUT11 shown in FIG. 1.

As shown in FIG. 2, one horizontal period is a period between a rising edge of a strobe signal STB serving as a pulse signal and a subsequent rising edge of the strobe signal STB. A charge sharing operation period is a period between a rising edge of the strobe signal STB and a falling edge of the strobe signal STB. In other words, the charge sharing operation period is provided at the beginning of one horizontal period, i.e., immediately after the switching of one horizontal period.

During the charge sharing operation, the charge share switch SW11 is turned on and the charge share switches SW12 and SW13 are also turned on. At the same time, the output switches SW14 and SW15 and the input switches SW16 and SW17 are turned off. This allows the electric charge of the loads F11 and F12 to be fed back to the non-inverting input terminals of the odd-numbered amplifier AMP11 and the even-numbered amplifier AMP12.

This operation allows the charge share voltages at the loads F11 and F12 to be transmitted to the input terminals of the odd-numbered amplifier AMP11 and the even-numbered amplifier AMP12 during the charge sharing operation. That is, the electric potentials at the output nodes SK11 and SG11, the odd-numbered output terminal SKOUT11, and the even-numbered output terminal SGOUT11 shown in FIG. 2 become substantially equal to each other.

After completion of the charge sharing operation period, in response to the falling edge of the strobe signal STB, the charge share switches SW11, SW12, and SW13 are turned off, and at the same time, the output switches SW14 and SW15 and the input switches SW16 and SW17 are turned on. Upon switching of the switches, the output voltages of the odd-numbered amplifier AMP 11 and the even-numbered amplifier AMP 12 become equal to the load voltage.

Upon turning on of the input switches SW16 and SW17, the inputs of the odd-numbered amplifier AMP 11 and the even-numbered amplifier AMP 12 are connected to a DA converter (not shown) which is provided at the pre-stage. After that, the outputs of the odd-numbered amplifier AMP 11 and the even-numbered amplifier AMP 12 smoothly shift to a set voltage.

Conventionally, the inputs of the odd-numbered amplifier AMP41 and the even-numbered amplifier AMP42 are switched to the set voltage during the charge sharing operation. Thus, the output voltages of the odd-numbered amplifier AMP41 and the even-numbered amplifier AMP42 temporarily become unequal to the load voltage after completion of the charge sharing operation.

Meanwhile, according to an exemplary embodiment of the present invention, the output voltages of the odd-numbered amplifier AMP11 and the even-numbered amplifier AMP12 can be set equal to the load voltage after completion of the charge sharing operation. Therefore, the fluctuation in the output of each of the odd-numbered amplifier AMP11 and the even-numbered amplifier AMP12 after completion of the charge sharing operation can be suppressed, and a peak circuit current (GND current) flowing immediately after the charge sharing operation can be reduced.

### Second Exemplary Embodiment

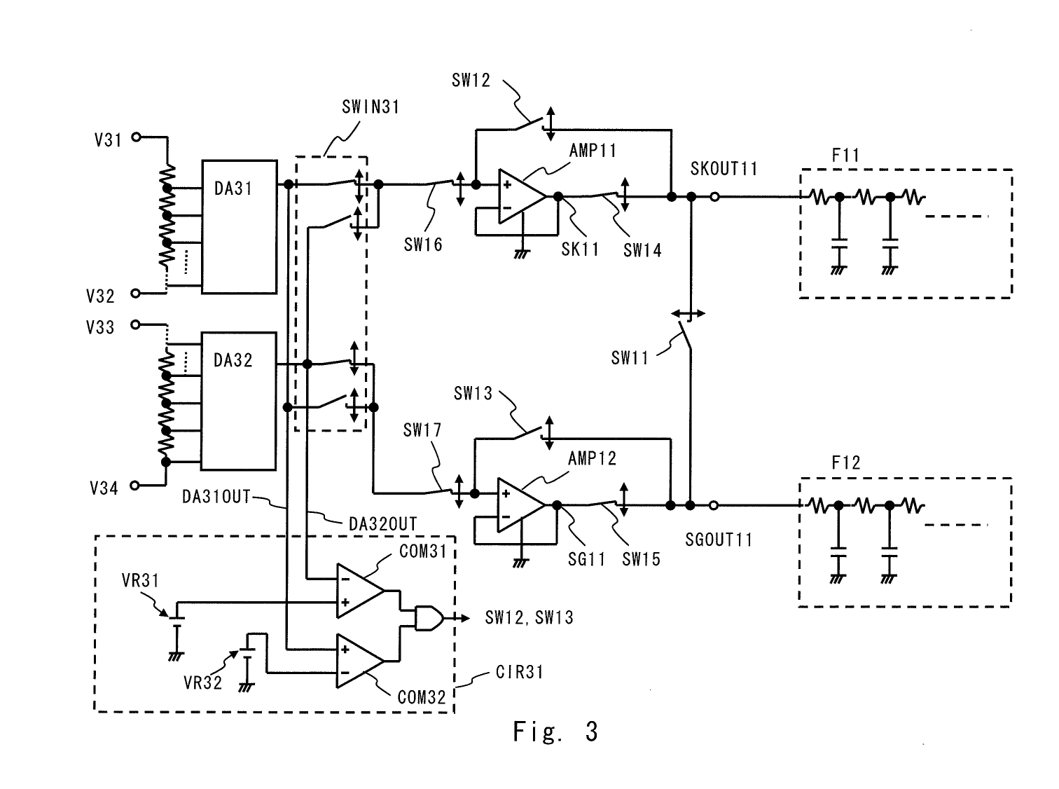

A liquid crystal display device using a signal line driving circuit according to a second exemplary embodiment of the present invention will be described with reference to FIG. 3. FIG. 3 is a diagram showing the configuration of the liquid crystal display device using the signal line driving circuit according to the second exemplary embodiment. Components in FIG. 3 that are identical to those of FIG. 1 are denoted by the same reference symbols, and the description thereof is omitted.

Referring to FIG. 3, unlike the configuration of the first exemplary embodiment shown in FIG. 1, the configuration of the second exemplary embodiment includes a voltage monitor circuit CIR31. A positive-side DA converter DA31 generates a positive-side grayscale voltage during inversion driving. A negative-side DA converter DA32 generates a negative-side grayscale voltage during inversion driving.

An input changeover switch SWIN31 connects the outputs of the positive-side DA converter DA31 and the negative-side DA converter DA32 to one of nodes, which are located on the left side of the input switches SW16 and SW17, in response to a polarity switching signal (not shown) during output inversion.

Specifically, the input changeover switch SWIN31 switches between a state in which the positive-side DA converter DA31 is connected to the input switch SW16 and further connected to the negative-side DA converter DA32 and the input switch SW17, and a state in which the positive-side DA converter DA31 is connected to the input switch SW17 and further connected to the negative-side DA converter DA32 and the input switch SW16.

The voltage monitor circuit CIR31 includes comparators COM31 and COM32 and reference power supplies VR31 and VR32. A non-inverting input terminal of the comparator COM31 is connected to the reference power supply VR31, and an inverting input terminal of the comparator COM31 is connected to an output DA32OUT of the negative-side DA converter DA32. The comparator COM31 compares the output DA32OUT with the reference power supply VR31, and outputs a comparison result.

A non-inverting input terminal of the comparator COM32 receives an output DA31OUT of the positive-side DA converter DA31, and an inverting-input terminal of the comparator COM32 is connected to the reference power supply VR32. The comparator COM32 compares the output DA31OUT with the reference power supply VR32, and outputs a comparison result.

The voltage monitor circuit CIR31 controls the charge share switches SW12 and SW13 and the input switches SW16 and SW17 according to the comparison results of the comparators COM31 and COM32. For example, when the amplitude at the time of dot inversion is greater than a predetermined value, i.e., when both the output DA31OUT from the positive-side DA converter DA31 and the output DA32OUT from the negative-side DA converter DA32 are greater than a predetermined reference voltage, the voltage monitor circuit CIR31 outputs an “H” signal.

In this case, during the charge sharing operation, the charge share switches SW12 and SW13 are turned on and the input switches SW16 and SW17 are turned off in response to the “H” signal from the voltage monitor circuit CIR31. This allows the charge share voltages to be fed back to the non-inverting input terminals of the odd-numbered amplifier AMP11 and the even-numbered amplifier AMP12. As a result, a peak circuit current (GND current) flowing immediately after the charge sharing operation can be reduced.

Meanwhile, when the amplitude at the time of dot inversion is equal to or less than the predetermined value, i.e., when at least one of the output DA31OUT from the positive-side DA converter DA31 and the output DA32OUT from the negative-side DA converter DA32 is equal to or less than the predetermined reference voltage, the voltage monitor circuit CIR31 outputs an “L” signal.

In this case, during the charge sharing operation, the charge share switches SW12 and SW13 are turned off and the input switches SW16 and SW17 are turned on in response to the “L” signal from the voltage monitor circuit CIR31. This prevents the charge share voltages from being fed back to the non-inverting input terminals of the odd-numbered amplifier AMP11 and the even-numbered amplifier AMP12.

Generally, when the amplitude is low at the time of dot inversion, the amount of the GND current is small. Accordingly, in this case, the charge share voltages are not fed back to the input terminals of the odd-numbered amplifier AMP11 and the even-numbered amplifier AMP12. Thus, when the function of allowing the charge share voltages to be fed back to the input terminals of the amplifiers is turned off, the slew rate of each amplifier at the low amplitude can be increased.

In this manner, the function of allowing the charge share voltages to be fed back to the amplifier input terminals is turned on and off depending on the magnitude of the grayscale voltage, thereby enabling switching between the priority to countermeasures against power supply noise and the EMI and the priority to the driving performance.

### Third Exemplary Embodiment

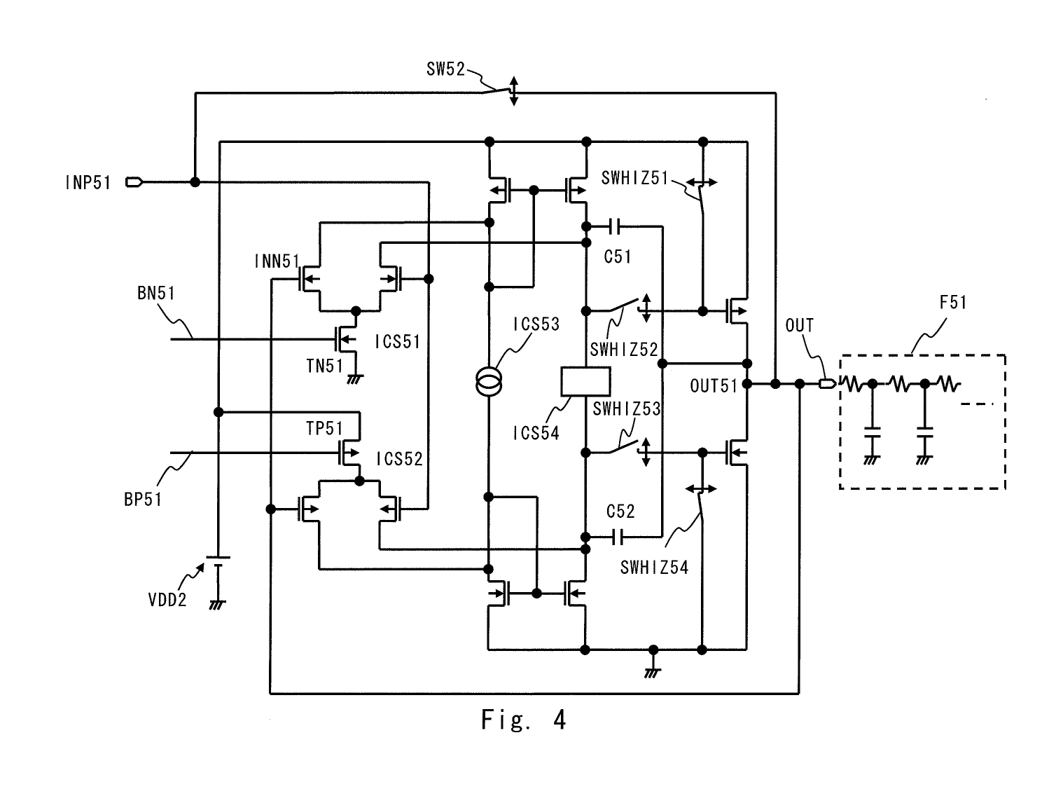

A liquid crystal display device using a signal line driving circuit according to a third exemplary embodiment of the present invention will be described with reference to FIG. 4. FIG. 4 is a diagram showing the configuration of the liquid crystal display device using the signal line driving circuit according to the third exemplary embodiment.

The signal line driving circuit according to the third exemplary embodiment includes an amplifier positive input terminal INP51, a bias power supply BN51, a bias power supply BP51, a power supply VDD2, an amplifier negative input terminal INN51, constant current sources ICS51, ICS52, and ICS53, a floating current source ICS54, a phase compensation capacitor C51, a phase compensation capacitor C52, switches SW52, SWHIZ51, SWHIZ52, SWHIZ53, and SWHIZ54, and an amplifier output terminal OUT51.

The amplifier output terminal OUT51 is connected to a load F51 of the liquid crystal panel. In the third exemplary embodiment, the output switches SW14 and SW15 for disconnecting the load from the amplifier output as shown in FIG. 1 are omitted, and the switches SHIZ51, SWHIZ52, SWHIZ53, and SWHIZ54 are provided in the amplifier. This allows the amplifier output terminal OUT51 to be placed in a high impedance state during the charge sharing operation.

Although not shown herein, a charge share switch is connected between an output terminal OUT of an odd-numbered amplifier and that of an even-numbered amplifier, as with the case of FIG. 1. The charge share switch SW52 is connected between a node between the charge share switch and the amplifier output terminal OUT51 and the amplifier positive input terminal INP51. The charge share switch SW52 corresponds to the charge share switches SW12 and SW13 shown in FIG. 1.

During the charge sharing operation, the switches SHIZ51, SWHIZ52, SWHIZ53, and SWHIZ54 are used to allow the amplifier output terminal OUT51 to be placed in the high impedance state, and allow the charge share switch SW52 to be turned on. As a result, the electric charge on the load F51 side can be fed back to the amplifier positive input terminal INP51.

Thus, as in the above exemplary embodiments, the output voltages of the odd- and even-numbered amplifiers and the load voltage do not compete against each another after completion of the charge sharing operation. Accordingly, the amplifier outputs smoothly shift toward the subsequent set voltage after the charge sharing operation, and thus an abrupt flow of the GND current or the high-potential-side power supply current is prevented. Further, in the third exemplary embodiment, the omission of the switches between the amplifier output and the load F51 results in an increase in the slew rate after the charge sharing operation.

While in the third exemplary embodiment, the charge share switch SW52 is connected between the node between the amplifier output terminal OUT51 and the output terminal OUT and the amplifier positive input terminal INP51, the location of the charge share switch SW52 is not limited thereto. The charge share switch SW52 may be connected between a charge sharing common line (not shown) and the amplifier positive input terminal INP51.

As described above, according to exemplary embodiments of the present invention, the amplifier output voltages and the load voltage can be set equal to each other during the charge sharing operation with a simple circuit configuration. As a result, the peak circuit current flowing immediately after the charge sharing operation can be reduced, and the EMI and power supply noise can also be reduced. Moreover, it is possible to switch between the priority to countermeasures against power supply noise and the EMI and the priority to the driving performance.

Note that the present invention is not limited to the exemplary embodiments described above, and various modifications can be made as needed without departing from the scope of the present invention. While this exemplary embodiment has illustrated an example in which the charge share switch SW11 is connected between the odd-numbered amplifier AMP11 and the even-numbered amplifier AMP12, the location of the charge share switch SW11 is not limited thereto. The charge share switch may be connected between a data line for transmitting a positive-side grayscale voltage and a data line for transmitting a negative-side grayscale voltage, regardless of whether the lines are odd-numbered or even-numbered lines.

Although omitted in FIG. 1 for ease of illustration, the positive-side DA converter DA31, the negative-side DA converter DA32, and the input changeover switch SWIN31 shown in FIG. 3 are also provided in the signal line driving circuit shown in FIG. 1. In the case of output inversion, the outputs of the positive-side DA converter DA31 and the negative-side DA converter D32 are switched and input to the input switches SW16 and SW17 in response to a polarity switching signal (not shown).

The first to third exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

1. A signal line driving circuit comprising:
a first amplifier;
a second amplifier;
a first charge share switch connected between an output terminal of the first amplifier and an output terminal of the second amplifier;
a first output switch connected between an output node of the first amplifier and the output terminal of the first amplifier;
a second charge share switch connected between a node between the first output switch and the output terminal of the first amplifier and an input terminal of the first amplifier; and
a first input switch connected to the input terminal of the first amplifier.

2. The signal line driving circuit according to claim 1, wherein each of the first charge share switch and the second charge share switch and each of the first output switch and the first input switch are exclusively set in a conductive state.

3. The signal line driving circuit according to claim 1, wherein during a charge sharing operation, the first charge share switch and the second charge share switch are on, and the first output switch and the first input switch are off.

4. The signal line driving circuit according to claim 1, further comprising a voltage monitor circuit that determines whether an output voltage of the first amplifier is equal to or less than a predetermined value,
wherein when the output voltage of the first amplifier is equal to or less than the predetermined value, the second charge share switch is turned off and the first input switch is turned on.

5. A signal line driving circuit comprising:
a first amplifier;
a second amplifier;
a first charge share switch connected between an output terminal of the first amplifier and an output terminal of the second amplifier;
a switch that is provided in the first amplifier and allows an output node of the first amplifier to be placed in a high impedance state; and
a second charge share switch connected between one of a node between the output node of the first amplifier and the output terminal of the first amplifier and a charge sharing common line, and an input terminal of the first amplifier.

6. The signal line driving circuit according to claim 5, wherein during a charge sharing operation, the first charge share switch and the second charge share switch are on, and the output node of the first amplifier is placed in a high impedance state.

7. The signal line driving circuit according to claim 1, wherein the first amplifier outputs an inverted voltage of an output voltage of the second amplifier.

8. A liquid crystal display device comprising:
a signal line driving circuit according to claim 1; and
a liquid crystal panel connected to the signal line driving circuit.

9. A liquid crystal display device comprising:
a signal line driving circuit according to claim 5; and
a liquid crystal panel connected to the signal line driving circuit.
